(19) United States
(12) Patent Application Publication
(10) Pub. No.: US 2026/0121649 A1
(43) Pub. Date: Apr. 30, 2026

(54) Harmonic compensation apparatus and method

(71) Applicant: REALTEK SEMICONDUCTOR CORPORATION, Hsinchu (TW)

(72) Inventors: Chung-Chieh Cheng, Hisinchu (TW); Yi-Chang Tu, Hsinchu (TW)

(21) Appl. No.: 19/003,277

(22) Filed: Dec. 27, 2024

(30) Foreign Application Priority Data
Jan. 8, 2024 (TW) 113100815

(51) Int. Cl. H03M 1/06

(52) U.S. Cl. CPC H03M 1/0614

(57) ABSTRACT

The presented harmonic compensation apparatus includes a harmonic compensation circuit, a conversion circuit, an analog output circuit and a compensation control circuit. The harmonic compensation circuit performs a harmonic generation process and a compensation adjusting process on a digital input signal according to a compensation parameter control signal to generate a harmonic compensation digital signal. The conversion circuit performs a harmonic compensation and a signal conversion on the digital input signal according to the harmonic compensation digital signal to generate an analog input signal. The analog output circuit generates an analog output signal to an external circuit according to the analog input signal and detects a loading state of the external circuit to generate a loading state detection signal, wherein the harmonic compensation eliminates a harmonic component of the analog output signal. The compensation control circuit generates the compensation parameter control signal according to the loading state.

### BACKGROUND OF THE INVENTION

### 1. Field of the Invention

The present invention relates to a harmonic compensation apparatus and a harmonic compensation method.

### 2. Description of Related Art

Operational amplifiers (OP) are widely used in analog circuits. However, if an intensity of at least one of signals inputted to an operational amplifier is too small or too large such that a voltage difference of the input terminals of the operational amplifier is too large, the operational amplifier operates in the saturation region (i.e., non-linear region) such that an output signal of the operational amplifier includes harmonics that results in the issue of harmonic distortion.

### SUMMARY OF THE INVENTION

In consideration of the problem of the prior art, an object of the present invention is to supply a harmonic compensation apparatus and a harmonic compensation method.

The present invention discloses a harmonic compensation apparatus that includes a harmonic compensation circuit, a conversion circuit, an analog output circuit and a compensation control circuit. The harmonic compensation circuit is configured to perform a harmonic generation process and a compensation adjusting process on a digital input signal according to a compensation parameter control signal to generate a harmonic compensation digital signal. The conversion circuit is configured to perform a harmonic compensation and a signal conversion on the digital input signal according to the harmonic compensation digital signal to generate an analog input signal. The analog output circuit is configured to generate an analog output signal to an external circuit according to the analog input signal and detect a loading state of the external circuit to generate a loading state detection signal, wherein the harmonic compensation eliminates a harmonic component of the analog output signal that is generated by the conversion circuit and the analog output circuit according to the digital input signal. The compensation control circuit is configured to generate the compensation parameter control signal according to the loading state detection signal.

The present invention also discloses a harmonic compensation method that includes steps outlined below. A harmonic generation process and a compensation adjusting process are performed on a digital input signal according to a compensation parameter control signal by a harmonic compensation circuit to generate a harmonic compensation digital signal. A harmonic compensation and a signal conversion are performed on the digital input signal according to the harmonic compensation digital signal by a conversion circuit to generate an analog input signal. An analog output signal is generated to an external circuit according to the analog input signal and a loading state of the external circuit is detected by an analog output circuit to generate a loading state detection signal, wherein the harmonic compensation eliminates a harmonic component of the analog output signal that is generated by the conversion circuit and the analog output circuit according to the digital input signal. The compensation parameter control signal is generated according to the loading state detection signal by a compensation control circuit.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1 illustrates a block diagram of a harmonic compensation apparatus and an external circuit electrically coupled to the harmonic compensation apparatus according to an embodiment of the present invention.

FIG. 2 illustrates a more detailed block diagram of the harmonic compensation circuit according to an embodiment of the present invention.

FIG. 3 illustrates a block diagram of a harmonic compensation apparatus and the external circuit electrically coupled to the harmonic compensation apparatus according to an embodiment of the present invention.

FIG. 4 illustrates a block diagram of a harmonic compensation apparatus and the external circuit electrically coupled to the harmonic compensation apparatus according to an embodiment of the present invention.

FIG. 5 illustrates a flow chart of a harmonic compensation method according to an embodiment of the present invention.

### DETAILED DESCRIPTION OF THE PREFERRED EMBODIMENTS

An aspect of the present invention is to provide a harmonic compensation apparatus and a harmonic compensation method that generate a compensation parameter control signal by a compensation control circuit according to a loading state detection signal related to a loading state of an external circuit such that the harmonic compensation circuit performs a harmonic generation process and a compensation adjusting process on a digital input signal accordingly to generate a harmonic compensation digital signal to eliminate or decrease harmonics of an analog output signal generated according to the digital input signal by an analog output circuit.

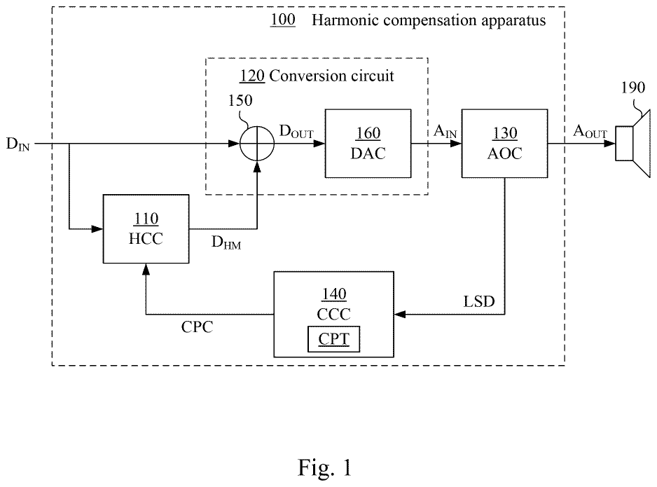

Reference is now made to FIG. 1. FIG. 1 illustrates a block diagram of a harmonic compensation apparatus 100 and an external circuit 190 electrically coupled to the harmonic compensation apparatus 100 according to an embodiment of the present invention.

The harmonic compensation apparatus 100 is configured to receive and process a digital input signal D_{IN} to generate an analog output signal A_{OUT}, and further transmit the analog output signal A_{OUT} to the external circuit 190.

In an embodiment, the digital input signal D_{IN} can be a single tone signal from such as, but not limited to an audio playback apparatus, and the external circuit 190 can be an audio amplifier. The harmonic compensation apparatus 100 may perform a harmonic compensation on the digital input signal D_{IN} according to a loading state of the external circuit 190 to generate the analog output signal A_{OUT}, such that the distortion occurs in the analog output signal A_{OUT} can be reduced.

The configuration and the operation of the harmonic compensation apparatus 100 are described in the following paragraphs.

The harmonic compensation apparatus 100 includes a harmonic compensation circuit 110 (abbreviated as HCC in FIG. 1), a conversion circuit 120, an analog output circuit 130 (abbreviated as AOC in FIG. 1) and a compensation control circuit 140 (abbreviated as CCC in FIG. 1).

The harmonic compensation circuit 110 configured to perform a harmonic generation process and a compensation adjusting process on the digital input signal D_{IN} according to a compensation parameter control signal CPC to generate a harmonic compensation digital signal D_{HM}.

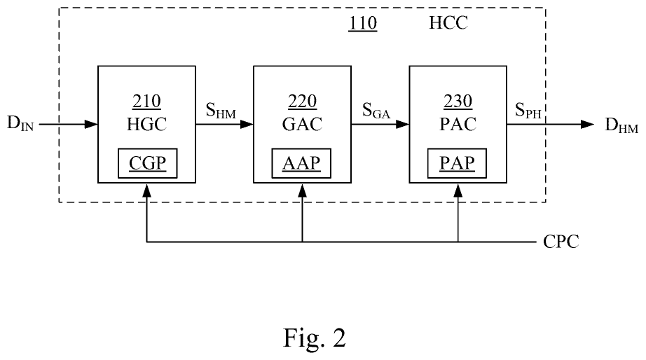

Reference is now made to FIG. 2. FIG. 2 illustrates a more detailed block diagram of the harmonic compensation circuit 110 according to an embodiment of the present invention. The harmonic compensation circuit 110 includes a harmonic generation circuit 210 (abbreviated as HGC in FIG. 2), a gain adjusting circuit 220 (abbreviated as GAC in FIG. 2) and a phase adjusting circuit 230 (abbreviated as PAC in FIG. 2).

The harmonic generation circuit 210 is configured to adjust a harmonic generation parameter CGP according to the compensation parameter control signal CPC to perform the harmonic generation process on the digital input signal D_{IN}, wherein the harmonic generation process generates K harmonic SHM according to the harmonic generation parameter CGP, and a frequency of each of the K harmonics SHM is N times of a frequency of the digital input signal D_{IN}, K being a positive integer (e.g., an integer not smaller than 2) and N being an integer larger than 1. The value of N is related to the types of the harmonics (e.g., integer multiple harmonics, non-integer multiple harmonics, high-order harmonics) included by the K harmonics SHM.

For example, when the frequency of the digital input signal D_{IN} is 1 KHz and the type of the harmonics included in the K harmonics SIM only includes the integer multiple harmonics, N is an integer being larger than 1. The K harmonics SHM can be signals of 2 KHz, 3 KHz, 4 KHz, . . . , etc, so on and so forth, in which the value of K is determined by practical requirements.

In an embodiment, the harmonic generation circuit 210 performs operation of the powers of 2, 3, 4, . . . , etc on the digital input signal D_{IN} according to the harmonic generation parameter CGP to generate the K harmonics SHM. Since the generation of the harmonics according to a given digital signal can be implemented by known or self-implemented technologies, the detail thereof is not described herein.

The gain adjusting circuit 220 is configured to adjust a gain adjusting parameter AAP according to the compensation parameter control signal CPC to perform a gain adjusting process of the compensation adjusting process, wherein the gain adjusting process adjusts gains of the K harmonics SHM according to the gain adjusting parameter AAP to generate K gain-adjusted harmonics SGA. The phase adjusting circuit 230 is configured to adjust a phase adjusting parameter PAP according to the compensation parameter control signal CPC to perform a phase adjusting process of the compensation adjusting process, wherein the phase adjusting process adjusts phases of the K gain-adjusted harmonics SGA according to the phase adjusting parameter PAP to generate the K phase-adjusted harmonics S_{PH} as the harmonic compensation digital signal D_{HM}.

The conversion circuit 120 performs a harmonic compensation and a signal conversion on the digital input signal D_{IN} according to the harmonic compensation digital signal Du to generate an analog input signal A_{IN}. In an embodiment, the conversion circuit 120 includes a mixer 150 and a digital-to-analog converter 160 (abbreviated as DAC in FIG. 1).

The mixer 150 is configured to perform the harmonic compensation (e.g., superimposition) on the digital input signal D_{IN} and the harmonic compensation digital signal D_{HM} to generate a digital output signal Dour. In a practical implementation, the harmonic compensation circuit 110 inverts the phase of the harmonic compensation digital signal D_{HM} such that the mixer 150 superimposes the digital input signal D_{IN} to the phase-inverted harmonic compensation digital signal D_{HM} to generate the digital output signal D_{OUT}.

In another practical implementation, the harmonic compensation circuit 110 does not invert the phase of the harmonic compensation digital signal D_{HM}. As a result, the mixer 150 minuses the harmonic compensation digital signal Duy from the digital input signal D_{IN} to generate the digital output signal Dorr. Since the phase-inverting process and the design of the mixer 150 can be implemented by known or self-implemented technologies, the detail thereof is not described herein.

The digital-to-analog converter 160 is configured to perform the signal conversion on the digital output signal Dour to generate the analog input signal AN.

The analog output circuit 130 is configured to generate the analog output signal A_{OUT} to the external circuit 190 according to the analog input signal AN and detect a loading state of the external circuit 190 to generate a loading state detection signal LSD, wherein the harmonic compensation described above eliminates a harmonic component of the analog output signal A_{OUT} that is generated by the conversion circuit 120 and the analog output circuit 130 according to the digital input signal D_{IN}. The compensation control circuit 140 is configured to generate the compensation parameter control signal CPC according to the loading state detection signal LSD, such that the harmonic compensation circuit 110 performs the processes described above according to the compensation parameter control signal CPC to generate the harmonic compensation digital signal D_{HM}.

In an embodiment, the analog output circuit 130 is configured to detect a current detection value and a voltage detection value of the analog output signal A_{OUT}, such that the loading state detection signal LSD generated thereby includes the current detection value and the current detection value, and the compensation control circuit 140 calculates an output wattage (e.g., a multiplication result of the current detection value and the voltage detection value) or a resistive value (e.g., a division result between the current detection value and the voltage detection value) according to the current detection value and the voltage detection value, and generates the compensation parameter control signal CPC according to the output wattage or the resistive value.

In another embodiment, the analog output circuit 130 is configured to detect the current detection value and the voltage detection value of the analog output signal A_{OUT}, and calculates the output wattage or the resistive value of the external circuit 190 according to the current detection value and the voltage detection value, such that the loading state detection signal LSD generated thereby includes the output wattage or the resistive value, and the compensation control circuit 140 generates the compensation parameter control signal CPC according to the output wattage or the resistive value.

In an embodiment, the compensation control circuit 140 is configured to store a compensation parameter look-up table CPT to look up the compensation parameter look-up table CPT according to the loading state detection signal LSD (e.g., after obtaining the output wattage or the resistive value) to generate the compensation parameter control signal CPC.

In an embodiment, at least one the digital-to-analog converter 160 and the analog output circuit 130 includes an analog electronic component (e.g., an operational amplifier), and such an analog electronic component operates in a non-linear region or a non-linear effect occurs thereto such that when the digital input signal D_{IN} is either too large or too small, the analog input signal Aix generate by the digital-to-analog converter 160 and the analog output signal A_{OUT} generated by the analog output circuit 130 may include harmonics that results in harmonic distortion.

The loading during the operation of the audio amplifier may vary due to different output wattages and resistive values such that the operation region of the audio amplifier is different. The harmonics generated thereby thus vary as well. As a result, the compensation control circuit 140 generates different contents of the compensation parameter control signal CPC according to the different contents of the loading state detection signal LSD related to the loading state of the external circuit 190. The harmonic generation circuit 210 further generates different contents of the harmonic compensation digital signal D_{HM} accordingly. Based on the compensation of the harmonic compensation digital signal D_{HM}, the harmonics of the analog input signal A and the analog output signal A_{OUT} generated under different loading conditions can be eliminated or reduced.

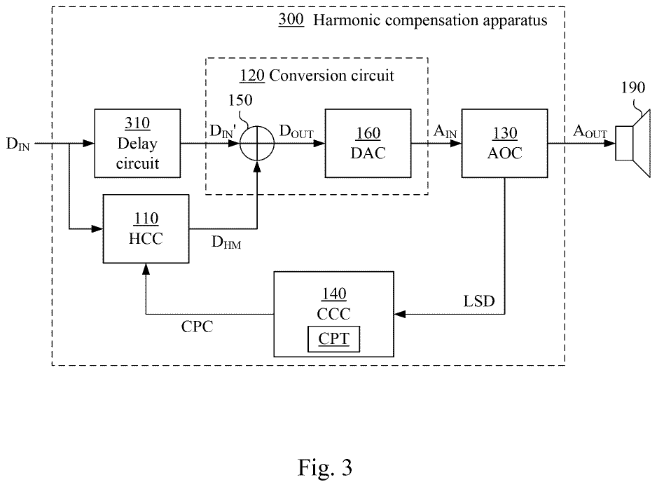

Reference is now made to FIG. 3. FIG. 3 illustrates a block diagram of a harmonic compensation apparatus 300 and the external circuit 190 electrically coupled to the harmonic compensation apparatus 300 according to an embodiment of the present invention.

Similar to the harmonic compensation apparatus 100 in FIG. 1, the harmonic compensation apparatus 300 includes the harmonic compensation circuit 110, the conversion circuit 120, the analog output circuit 130 and the compensation control circuit 140. However, the harmonic compensation apparatus 300 of the present embodiment further includes a delay circuit 310.

The delay circuit 310 is configured to perform a delay operation on the digital input signal D_{IN} and transmit the delayed digital input signal D_{IN} to the conversion circuit 120. More specifically, the delay circuit 310 is used to cancel or decrease the transmission delay of the operation of the harmonic compensation circuit 110 such that the digital input signal D_{IN} corresponding to a certain time point and the harmonic compensation digital signal Dum generated accordingly can arrive the mixer 150. In FIG. 3, the delay circuit 310 is used to delay the digital input signal D_{IN} and outputs the delayed digital input signal D_{IN}′ to the conversion circuit 120.

The delay amount of the delay operation is determined by the signal processing time of the harmonic compensation circuit 110. For example, when the signal processing time of the harmonic compensation circuit 110 is equivalent to a time of X reference clock cycles, the delay amount of the delay operation is set according to the time of the X reference clock cycles (e.g., the delay amount is set to equal to the time of the X reference clock cycles), wherein the reference clock is the operation clock of the harmonic compensation circuit 110 or other clocks that can quantize the transmission delay, X being an integer. The transmission delay (the time of the X clock cycles) can be obtained by using known or self-implemented simulation and analysis tools, by using an external instrument to perform measurement or by using a clock counter.

In an embodiment, the delay circuit 310 in FIG. 3 can be used to replace the phase adjusting circuit 230 in FIG. 2. More specifically, both the delay circuit 310 and the phase adjusting circuit 230 are used to adjust the phase relation between the digital input signal D_{IN} and the harmonic compensation digital signal D_{HM}. As a result, the phase adjusting amount contributed by the phase adjusting circuit 230 can be alternatively provided by the delay circuit 310. Under such a condition, the phase adjusting circuit 230 can be removed, and the K gain-adjusted harmonics SGA serves as the harmonic compensation digital signal D_{HM}. Under such a condition, the delay amount of the delay operation is determined by the signal processing time of the harmonic compensation circuit 110 and the analog output signal A_{OUT}.

Corresponding to the embodiment described above, the compensation parameter control signal CPC generated by the compensation control circuit 140 may selectively include a delay adjusting parameter DAP to adjust the delay amount of the delay operation.

On the other hand, the delay amount of the delay operation may also be implemented by using the phase adjusting circuit 230. Under such a condition, the delay circuit 310 is removed such that the harmonic compensation apparatus includes the configuration illustrated in FIG. 1. The present invention is not limited thereto.

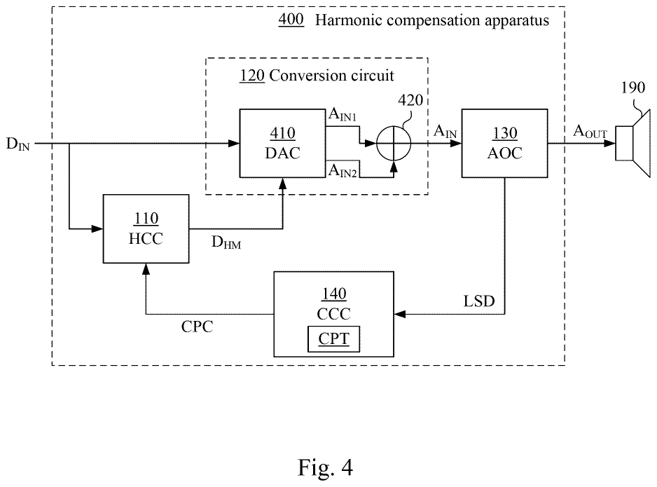

Reference is now made to FIG. 4. FIG. 4 a block diagram of a harmonic compensation apparatus 400 and the external circuit 190 electrically coupled to the harmonic compensation apparatus 400 according to an embodiment of the present invention.

Similar to the harmonic compensation apparatus 100 in FIG. 1, the harmonic compensation apparatus 400 includes the harmonic compensation circuit 110, the conversion circuit 120, the analog output circuit 130 and the compensation control circuit 140. However, the conversion circuit 120 of the present embodiment includes a digital-to-analog converter 410 (abbreviated as DAC in FIG. 4) and a mixer 420.

The digital-to-analog converter 410 is configured to perform the signal conversion on the digital input signal Dix to generate a first the analog input signal ANI, and perform the signal conversion on the harmonic compensation digital signal D_{HM} to generate a second the analog input signal A_{IN2}.

The mixer 420 is configured to perform the harmonic compensation (e.g., the superimposition) on the first the analog input signal A_{IN1} and the second the analog input signal A_{IN2} to generate the analog input signal A_{IN}. Similarly, the harmonic compensation circuit 110 may invert the phase of the harmonic compensation digital signal D_{HM}, such that the digital-to-analog converter 410 converts the digital input signal D_{IN} and the phase-inverted harmonic compensation digital signal D_{HM} and the mixer 420 superimposes the received first the analog input signal A_{IN1} to the received second the analog input signal A_{IN2} to generate the analog input signal A_{IN}.

In another practical implementation, the harmonic compensation circuit 110 does not invert the phase of the harmonic compensation digital signal D_{HM}. As a result, the digital-to-analog converter 410 performs signal conversion on the digital input signal D_{IN} and the harmonic compensation digital signal D_{HM}, and the mixer 420 minuses the second the analog input signal A_{IN2} from the first the analog input signal A_{IN1} to generate the analog input signal A_{IN}.

The harmonic compensation apparatus of the present invention generates a compensation parameter control signal by a compensation control circuit according to a loading state detection signal related to a loading state of an external circuit such that the harmonic compensation circuit performs a harmonic generation process and a compensation adjusting process on a digital input signal accordingly to generate a harmonic compensation digital signal to eliminate or decrease harmonics of an analog output signal generated according to the digital input signal by an analog output circuit.

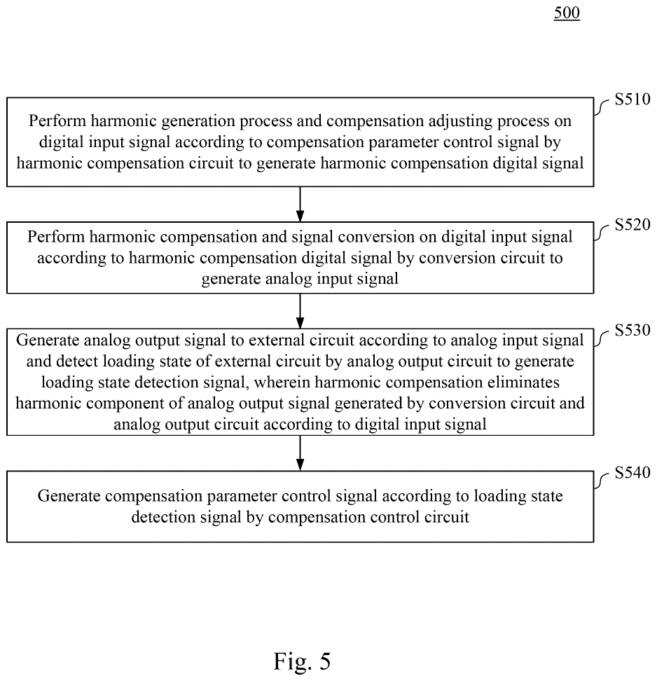

Reference is now made to FIG. 5. FIG. 5 illustrates a flow chart of a harmonic compensation method 500 according to an embodiment of the present invention.

In addition to the apparatus described above, the present disclosure further provides the harmonic compensation method 500 that can be used in such as, but not limited to, the harmonic compensation apparatus 100 in FIG. 1. As illustrated in FIG. 5, an embodiment of the harmonic compensation method 500 includes the following steps.

In step S510, the harmonic generation process and the compensation adjusting process are performed on the digital input signal D_{IN} according to the compensation parameter control signal CPC by the harmonic compensation circuit 110 to generate the harmonic compensation digital signal D_{HM}.

In step S520, the harmonic compensation and the signal conversion are performed on the digital input signal D_{IN} according to the harmonic compensation digital signal Du by the conversion circuit 120 to generate the analog input signal A_{IN}.

In step S530, the analog output signal A_{OUT} is generated to the external circuit 190 according to the analog input signal A_{IN} and the loading state of the external circuit 190 is detected by the analog output circuit 130 to generate the loading state detection signal LSD, wherein the harmonic compensation eliminates a harmonic component of the analog output signal A_{OUT} that is generated by the conversion circuit 120 and the analog output circuit 130 according to the digital input signal D_{IN}.

In step S540, the compensation parameter control signal CPC is generated according to the loading state detection signal LSD by the compensation control circuit 140.

It is appreciated that the embodiments described above are merely an example. In other embodiments, it should be appreciated that many modifications and changes may be made by those of ordinary skill in the art without departing, from the spirit of the disclosure. Further, it is appreciated that a non-linear operation of other circuits besides the operational amplifier (e.g., a frequency multiplier) may also results in harmonics. Since the parameters of the harmonic compensation circuit are determined according to the harmonics of the analog output signal in the present invention, the harmonic can be compensated whether the harmonics are induced by the operational amplifier or other circuits.

In summary, the present invention discloses the harmonic compensation apparatus and the harmonic compensation method that generate a compensation parameter control signal by a compensation control circuit according to a loading state detection signal related to a loading state of an external circuit such that the harmonic compensation circuit performs a harmonic generation process and a compensation adjusting process on a digital input signal accordingly to generate a harmonic compensation digital signal to eliminate or decrease harmonics of an analog output signal generated according to the digital input signal by an analog output circuit.

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. A harmonic compensation apparatus, comprising:
a harmonic compensation circuit configured to perform a harmonic generation process and a compensation adjusting process on a digital input signal according to a compensation parameter control signal to generate a harmonic compensation digital signal;
a conversion circuit configured to perform a harmonic compensation and a signal conversion on the digital input signal according to the harmonic compensation digital signal to generate an analog input signal;
an analog output circuit configured to generate an analog output signal to an external circuit according to the analog input signal and detect a loading state of the external circuit to generate a loading state detection signal, wherein the harmonic compensation eliminates a harmonic component of the analog output signal that is generated by the conversion circuit and the analog output circuit according to the digital input signal; and
a compensation control circuit configured to generate the compensation parameter control signal according to the loading state detection signal.

2. The harmonic compensation apparatus of claim 1, wherein the analog output circuit is configured to detect a current detection value and a voltage detection value of the analog output signal such that the loading state detection signal generated thereby comprises the current detection value and the voltage detection value, and the compensation control circuit calculates an output wattage or a resistive value of the external circuit according to the current detection value and the voltage detection value and generates the compensation parameter control signal according to the output wattage or the resistive value.

3. The harmonic compensation apparatus of claim 1, wherein the analog output circuit is configured to detect a current detection value and a voltage detection value of the analog output signal and calculates an output wattage or a resistive value of the external circuit according to the current detection value and the voltage detection value such that the loading state detection signal generated thereby comprises the output wattage or the resistive value, and the compensation control circuit generates the compensation parameter control signal according to the output wattage or the resistive value.

4. The harmonic compensation apparatus of claim 1, wherein the compensation control circuit is configured to store a compensation parameter look-up table to look up the compensation parameter look-up table according to the loading state detection signal to generate the compensation parameter control signal.

5. The harmonic compensation apparatus of claim 1, wherein the conversion circuit comprises:
a mixer configured to perform the harmonic compensation on the digital input signal and the harmonic compensation digital signal to generate a digital output signal; and
a digital-to-analog converter configured to perform the signal conversion on the digital output signal to generate the analog input signal.

6. The harmonic compensation apparatus of claim 1, wherein the conversion circuit comprises:
a digital-to-analog converter configured to perform the signal conversion on the digital input signal to generate a first analog input signal, and perform the signal conversion on the harmonic compensation digital signal to generate a second analog input signal; and
a mixer configured to perform the harmonic compensation on the first the analog input signal and the second analog input signal to generate the analog input signal.

7. The harmonic compensation apparatus of claim 1, wherein the harmonic compensation circuit comprises:
a harmonic generation circuit configured to adjust a harmonic generation parameter according to the compensation parameter control signal to perform the harmonic generation process on the digital input signal, wherein the harmonic generation process generates K harmonics according to the harmonic generation parameter, and a frequency of each of the K harmonics is N times of a frequency of the digital input signal, K being a positive integer and N being an integer larger than 1; and
a gain adjusting circuit configured to adjust a gain adjusting parameter according to the compensation parameter control signal to perform a gain adjusting process of the compensation adjusting process, wherein the gain adjusting process adjusts gains of the K harmonics according to the gain adjusting parameter to generate K gain-adjusted harmonics;
wherein the harmonic compensation digital signal is the K gain-adjusted harmonics or K phase-adjusted harmonics generated according to the K gain-adjusted harmonics.

8. The harmonic compensation apparatus of claim 7, wherein the harmonic compensation circuit comprises:
a phase adjusting circuit configured to adjust a phase adjusting parameter according to the compensation parameter control signal to perform a phase adjusting process of the compensation adjusting process, wherein the phase adjusting process adjusts phases of the K gain-adjusted harmonics according to the phase adjusting parameter to generate the K phase-adjusted harmonics as the harmonic compensation digital signal.

9. The harmonic compensation apparatus of claim 7, further comprising:
a delay circuit configured to perform a delay operation on the digital input signal and transmit the delayed digital input signal to the conversion circuit, wherein a delay amount of the delay operation is determined by a signal processing time of the harmonic compensation circuit.

10. The harmonic compensation apparatus of claim 9, wherein the delay amount of the delay operation is determined by the signal processing time of the harmonic compensation circuit and the analog output signal, and the harmonic compensation digital signal is the K gain-adjusted harmonics.

11. A harmonic compensation method, comprising:
performing a harmonic generation process and a compensation adjusting process on a digital input signal according to a compensation parameter control signal by a harmonic compensation circuit to generate a harmonic compensation digital signal;
performing a harmonic compensation and a signal conversion on the digital input signal according to the harmonic compensation digital signal by a conversion circuit to generate an analog input signal;
generating an analog output signal to an external circuit according to the analog input signal and detecting a loading state of the external circuit by an analog output circuit to generate a loading state detection signal, wherein the harmonic compensation eliminates a harmonic component of the analog output signal that is generated by the conversion circuit and the analog output circuit according to the digital input signal; and
generating the compensation parameter control signal according to the loading state detection signal by a compensation control circuit.

12. The harmonic compensation method of claim 11, further comprising:
detecting a current detection value and a voltage detection value of the analog output signal by the analog output circuit such that the loading state detection signal generated thereby comprises the current detection value and the voltage detection value; and
calculating an output wattage or a resistive value of the external circuit according to the current detection value and the voltage detection value by the compensation control circuit and generating the compensation parameter control signal according to the output wattage or the resistive value by the compensation control circuit.

13. The harmonic compensation method of claim 11, further comprising:
detecting a current detection value and a voltage detection value of the analog output signal by the analog output circuit;
calculating an output wattage or a resistive value of the external circuit according to the current detection value and the voltage detection value by the analog output circuit such that the loading state detection signal generated thereby comprises the output wattage or the resistive value; and
generating the compensation parameter control signal according to the output wattage or the resistive value by the compensation control circuit.

14. The harmonic compensation method of claim 11, further comprising:
storing a compensation parameter look-up table by the compensation control circuit to look up the compensation parameter look-up table according to the loading state detection signal to generate the compensation parameter control signal.

15. The harmonic compensation method of claim 11, further comprising:
performing the harmonic compensation on the digital input signal and the harmonic compensation digital signal by a mixer comprised the conversion circuit to generate a digital output signal; and
performing the signal conversion on the digital output signal by a digital-to-analog converter comprised by the conversion circuit to generate the analog input signal.

16. The harmonic compensation method of claim 11, further comprising:
performing the signal conversion on the digital input signal by a digital-to-analog converter comprised the conversion circuit to generate a first analog input signal, and performing the signal conversion on the harmonic compensation digital signal by the digital-to-analog converter of the conversion circuit to generate a second analog input signal; and
performing the harmonic compensation on the first the analog input signal and the second analog input signal by a mixer comprised the conversion circuit to generate the analog input signal.

17. The harmonic compensation method of claim 11, further comprising:
adjusting a harmonic generation parameter according to the compensation parameter control signal by a harmonic generation circuit comprised the harmonic compensation circuit to perform the harmonic generation process on the digital input signal, wherein the harmonic generation process generates K harmonics according to the harmonic generation parameter, and a frequency of each of the K harmonics is N times of a frequency of the digital input signal, K being a positive integer and N being an integer larger than 1; and
adjusting a gain adjusting parameter according to the compensation parameter control signal by a gain adjusting circuit comprised the harmonic compensation circuit to perform a gain adjusting process of the compensation adjusting process, wherein the gain adjusting process adjusts gains of the K harmonics according to the gain adjusting parameter to generate K gain-adjusted harmonics;
wherein the harmonic compensation digital signal is the K gain-adjusted harmonics or K phase-adjusted harmonics generated according to the K gain-adjusted harmonics.

18. The harmonic compensation method of claim 17, further comprising:
adjusting a phase adjusting parameter according to the compensation parameter control signal by a phase adjusting circuit comprised by the harmonic compensation circuit to perform a phase adjusting process of the compensation adjusting process, wherein the phase adjusting process adjusts phases of the K gain-adjusted harmonics according to the phase adjusting parameter to generate the K phase-adjusted harmonics as the harmonic compensation digital signal.

19. The harmonic compensation method of claim 17, further comprising:
performing a delay operation on the digital input signal and transmitting the delayed digital input signal to the conversion circuit by a delay circuit, wherein a delay amount of the delay operation is determined by a signal processing time of the harmonic compensation circuit.

20. The harmonic compensation method of claim 19, wherein the delay amount of the delay operation is determined by the signal processing time of the harmonic compensation circuit and the analog output signal, and the harmonic compensation digital signal is the K gain-adjusted harmonics.
